(19) United States
(12) Patent Application Publication
(10) Pub. No.: US 2011/0259385 A1
(43) Pub. Date: Oct. 27, 2011

(54) THERMOELECTRIC CONVERSION MODULE AND THERMOELECTRIC CONVERSION MODULE BLOCK

(75) Inventor: Yuichi Hiroyama, Ibaraki (JP)

(73) Assignee: SUMITOMO CHEMICAL COMPANY, LIMITED, Chuo-ku, Tokyo (JP)

(21) Appl. No.: 13/143,380

(22) PCT Filed: Jan. 8, 2010
(86) PCT No.: PCT/JP2010/050163

§ 371 Date: Jul. 6, 2011

(30) Foreign Application Priority Data
Jan. 15, 2009 (JP) 2009-006650

(51) Int. Cl. H01L 35/32

(52) U.S. Cl. 136/205; 136/224

(57) ABSTRACT

(Problem) To make a thermoelectric conversion module block with a plurality of connected thermoelectric conversion modules easy to handle and easy to connect the thermoelectric conversion modules to one another, operate stably for long periods of time.

(Solution to problem) A thermoelectric conversion module is provided with a substrate 2, and a plurality of thermoelectric conversion elements 3, 4 electrically connected in series to one another on the substrate 2. A bottom face 2u of one end portion 2A of the substrate 2 is higher than a bottom face 2u of an other end portion 2B of the substrate 2 and a top face 2t of the one end portion 2A of the substrate 2 is higher than a top face 2t of the other end portion 2B of the substrate 2; through holes 12, 13 are formed in each of the one end portion 2A and the other end portion 2B of the substrate 2; in the one end portion 2A of the substrate 2, one end portion electrode layer 8a electrically connected to one end E1 of the plurality of thermoelectric conversion elements 3, 4 is provided ranging from the top face 2t through an interior surface of the through hole 12 to a surrounding region around the through hole 12 in the bottom face 2u; in the other end portion 2B of the substrate 2 an other end portion electrode layer 8b electrically connected to the other end E2 of the plurality of thermoelectric conversion elements 3, 4 is provided on a surrounding region around the through hole 13 in the top face 2t.

### TECHNICAL FIELD

The present invention relates to a thermoelectric conversion module and a thermoelectric conversion module block.

### BACKGROUND ART

There is a conventionally known thermoelectric conversion module wherein n-type and p-type thermoelectric conversion elements connected in series to one another are arranged on a substrate, as an element that generates electric power by making use of temperature difference. For obtaining high output power, a plurality of thermoelectric conversion modules are further connected in series to one another in some cases. As a thermoelectric conversion module allowing such connection, Patent Literature 1 discloses the thermoelectric conversion module with electrode plates for connection to other modules extending from the both ends of the substrate. Furthermore, Patent Literature 2 discloses that the thermoelectric conversion modules are connected to each other by means of lead wires.

### CITATION LIST

### Patent Literatures

Patent Literature 1: JP2008-108900A

Patent Literature 2: JP2000-252528A

### SUMMARY OF INVENTION

### Technical Problem

When the electrodes are projecting out from the substrate, it becomes difficult to handle the thermoelectric conversion module and, in the case where the plurality of thermoelectric conversion modules are connected to one another by bonding the electrodes to each other, the electrodes mainly support vibration from the outside, thermal stress, etc., which makes it difficult to make the thermoelectric conversion modules operate stably for long periods of time. On the other hand, it is cumbersome to connect the thermoelectric conversion modules to one another by means of lead wires.

The present invention has been accomplished in view of the above problem and it is an object of the present invention to provide a thermoelectric conversion module being easy to handle and to be connected to another thermoelectric conversion module and allowing a thermoelectric conversion module block composed of a plurality of connected thermoelectric conversion modules to operate stably for long periods of time, and a thermoelectric conversion module block employing the thermoelectric conversion module.

### Solution to Problem

A thermoelectric conversion module according to the present invention comprises: a substrate having a top face and a bottom face opposing each other; and a plurality of thermoelectric conversion elements arranged on the top face of the substrate and electrically connected in series to one another. The bottom face of one end portion of the substrate is higher than the bottom face of the other end portion of the substrate and the top face of the one end portion of the substrate is higher than the top face of the other end portion of the substrate. A through hole is formed in each of the one end portion and the other end portion of the substrate. In the one end portion of the substrate, an one end portion electrode layer electrically connected to one end of the plurality of thermoelectric conversion elements is provided ranging from the top face through an interior surface of the through hole to a surrounding region around the through hole in the bottom face. In the other end portion of the substrate, an other end portion electrode layer electrically connected to the other end of the plurality of thermoelectric conversion elements is provided on a surrounding region around the through hole in the top face.

A thermoelectric conversion module block according to the present invention comprises a plurality of thermoelectric conversion modules as mentioned above, the one end portion of the substrate of one thermoelectric conversion module is superimposed on the other end portion of the substrate of another thermoelectric conversion module, and each pair of substrates are secured by a fixing member penetrating through the through hole in the one end portion and the through hole in the other end portion.

According to the present invention, there is a level difference made between the one end portion and the other end portion of the substrate and this level difference can be used to achieve easy superposition of the one end portion of one substrate and the other end portion of another substrate; the substrates are superimposed on each other in this manner and the fixing member penetrates through the respective through holes of the pair of substrates, whereby the two substrates can be readily secured in close contact and the one end portion electrode layer and the other end portion electrode layer can be surely brought into contact with each other, making it easy to electrically bring the thermoelectric conversion modules into connect with each other. Since the thermoelectric conversion modules are secured to each other by letting the fixing member penetrate through the through holes of the pair of substrates, the mechanical structure of the block is not maintained mainly by the electrodes but is maintained mainly by the fixing member and substrates. Therefore, the mechanical strength of the block is also high and breakage or the like of the joint part due to vibration or thermal stress is also suppressed more than in the case where the projecting electrodes are bonded to each other.

Preferably, a heat sink with through holes corresponding to the through holes of the substrates is arranged on the bottom faces of the substrates and the fixing member further penetrates through the through hole of the heat sink to secure the heat sink to the pair of substrates. This further allows the heat sink to be also secured using the through hole.

### Advantageous Effects of Invention

The present invention provides the thermoelectric conversion module which is easy to handle, which is prevented from breaking, and which is easy to be connected to another thermoelectric conversion module, and the thermoelectric conversion module block employing it.

### BRIEF DESCRIPTION OF DRAWINGS

FIG. 1 is a partly broken top plan view of thermoelectric conversion module 1 according to an embodiment.

FIG. 2 is a cross-sectional view along the line I-I in FIG. 1.

FIG. 3 is a schematic cross-sectional view of thermoelectric conversion module block 100 using the thermoelectric conversion module 1 of FIG. 1.

FIG. 4 is a schematic cross-sectional view showing a modification example of the thermoelectric conversion module block 100.

FIG. 5 is a drawing showing a first modification example of the thermoelectric conversion module 1.

FIG. 6 is a drawing showing a second modification example of the thermoelectric conversion module 1.

FIG. 7 is a drawing showing a third modification example of the thermoelectric conversion module 1.

### DESCRIPTION OF EMBODIMENTS

The preferred embodiments of the present invention will be described below in detail with reference to the accompanying drawings. In the description of the drawings, identical or equivalent elements will be denoted by the same reference signs, without redundant description. It is also noted that dimensional ratios in each drawing do not always coincide with actual dimensional ratios.

### (Thermoelectric Conversion Module of First Embodiment)

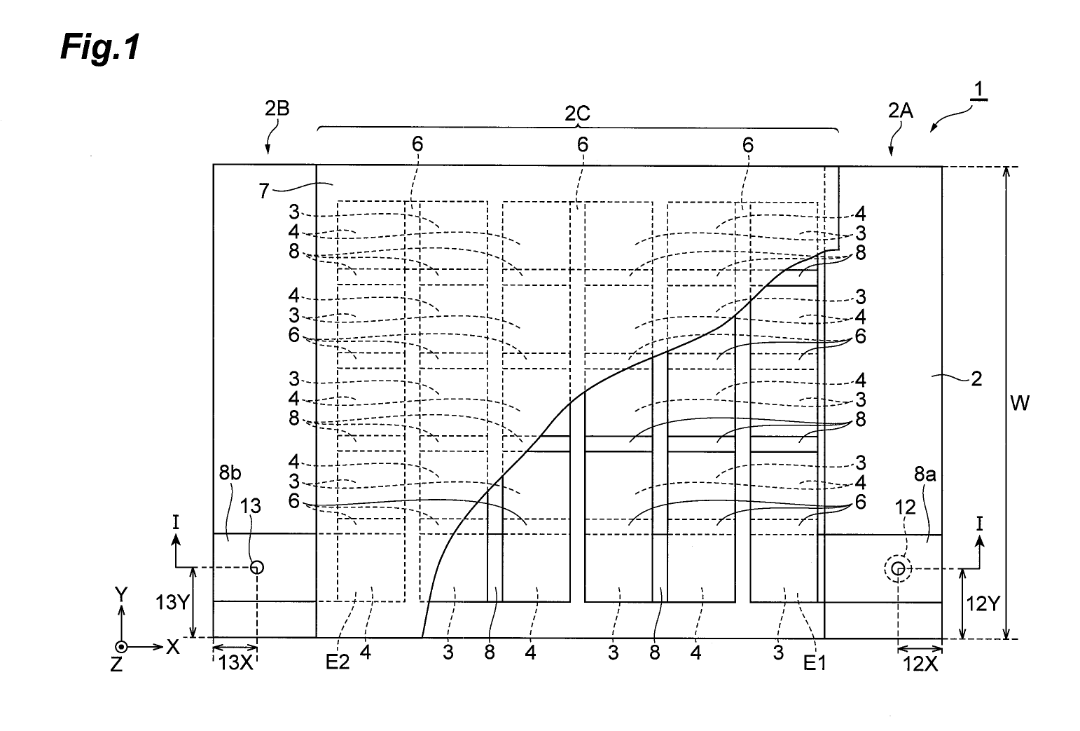

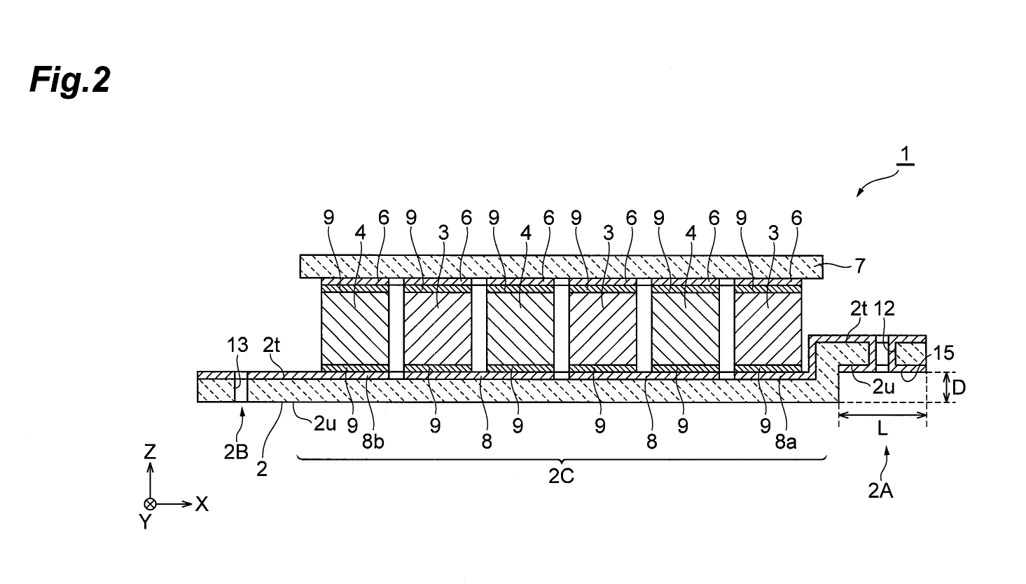

FIG. 1 is a partly broken top plan view of thermoelectric conversion module 1 according to the first embodiment. In the drawing the rightward direction is defined as an X-direction, an upward direction as a Y-direction, and a direction extending outwardly hither from the drawing, as a Z-direction. FIG. 2 is a cross-sectional view along the line I-I in FIG. 1. The thermoelectric conversion module 1 of the present embodiment is provided mainly with a first substrate 2, first electrodes 8, p-type thermoelectric conversion elements 3, n-type thermoelectric conversion elements 4, second electrodes 6, and a second substrate 7. The p-type thermoelectric conversion elements 3 and n-type thermoelectric conversion elements 4 are alternately arranged side by side in a matrix pattern between the first substrate 2 and the second substrate 7 and, on the whole, their both faces are electrically connected in series to one another by the corresponding first electrodes 8 and second electrodes 6.

The first substrate 2 has, for example, a rectangular shape, has an electrical insulation property and a thermal conduction property, and covers one ends of the thermoelectric conversion elements 3, 4. Examples of materials applicable to this first substrate include alumina, aluminum nitride, magnesia, silicon carbide, zirconia, and mullite.

The first substrate 2, as shown in FIG. 2, has a bottom face 2u and a top face 2t opposing each other, and further has one end portion 2A on one longitudinal side (the right side in the drawing), the other end portion 2B on the other longitudinal side (the left side in the drawing), and a central portion 2C interposed between these one end portion 2A and other end portion 2B.

The first electrodes 8 are provided on the central portion 2C of the first substrate 2 and each first electrode 8 electrically connects lower end faces of p-type thermoelectric conversion element 3 and n-type thermoelectric conversion element 4 adjacent to each other. The first electrodes 8 can be formed at prescribed positions on the central portion 2C on the first substrate 2 by a method of, for example, a thin film technology of such as sputtering and evaporation, screen printing, plating, or thermal spraying. They can also be formed, for example, by bonding metal sheets of a prescribed shape or the like onto the first substrate 2 by soldering, brazing, or the like. While there are no particular restrictions on a material of the first electrodes 8 as long as it has an electrically conductive property, in terms of improvement in heat resistance, corrosion resistance, and adhesion of the electrodes to the thermoelectric elements, it is preferable to adopt a metal containing, as a major ingredient, at least one element selected from the group consisting of titanium, vanadium, chromium, manganese, iron, cobalt, nickel, copper, molybdenum, silver, palladium, gold, tungsten, and aluminum. The major ingredient herein refers to an ingredient contained 50% by volume or more in the electrode material.

The first electrodes 8 are preferably bonded through a joint material 9 to the p-type thermoelectric conversion elements 3 and the n-type thermoelectric conversion elements 4. The joint material 9 applicable herein can be, for example, a solder of AuSb or PbSb type, and a silver paste. This joint material is preferably one which stays solid during use as the thermoelectric conversion module. The p-type thermoelectric conversion elements 3 and the n-type thermoelectric conversion elements 4 can be those with a metal layer on a surface opposing the first electrode 8.

The p-type thermoelectric conversion elements 3 and the n-type thermoelectric conversion elements 4 are arranged on the first electrodes 8. While there are no particular restrictions on the shape of the p-type thermoelectric conversion elements 3 and the n-type thermoelectric conversion elements 4, a preferred form is a pillar shape, preferably, a quadrangular prism shape.

While there are no particular restrictions on materials making up the p-type thermoelectric conversion elements 3 and the n-type thermoelectric conversion elements 4 as long as they have a property of a p-type semiconductor or an n-type semiconductor, they can be made using a variety of materials such as metals and metal oxides.

The materials applicable to the p-type thermoelectric conversion elements 3 and the n-type thermoelectric conversion elements 4 herein include those listed below.

Examples of p-type materials include: mixed metal oxides such as NaₓCoO₂ (0<x<1) and Ca₃Co₄O₉; silicides such as MnSi_{1.73} Fe₁₋ₓMnₓSi₂, Si_{0.8}Ge_{0.2}:B (B-doped Si_{0.8}Ge_{0.2}), and β-FeSi₂; skutterudites such as CoSb₃, FeSb₃, and RFe₃CoSb₁₂ (where R represents La, Ce, or Yb); Te-containing alloys such as BiTeSb, PbTeSb, Bi₂Te₃, PbTe, and Sb₂Te₃; and Zn₄Sb₃.

Examples of n-type materials include: mixed metal oxides such as SrTiO₃, Znᵢ₋ₓAlₓO, CaMnO₃, LaNiO₃, BaTiO₃, and Tiᵢ₋ₓNbₓO; silicides such as Mg₂Si, Fe₁₋ₓCoₓSi₂, Si_{0.8}Ge_{0.2}:P (P-doped Si_{0.8}Ge_{0.2}), and β-FeSi₂; skutterudites such as CoSb₃; clathrate compounds such as Ba₈Al₁₂Si₃₀, Ba₈AlₓSi₄₆₋ₓ, Ba₈Al₁₂Ge₃₀, and Ba₈AlₓGe₄₆₋ₓ; boron compounds such as CaB₆, SrB₆, BaB₆, and CeB₆; Te-containing alloys such as BiTeSb, PbTeSb, Bi₂Te₃, Sb₂Te₃, PbTe, and Sb₂Te₃; and Zn₄Sb₃.

When consideration is given to situations where the thermoelectric conversion module is used at 300° C. or higher, the p-type thermoelectric conversion elements and the n-type thermoelectric conversion elements preferably contain a metal oxide as a major ingredient among the above-listed materials, in terms of heat resistance and oxidation resistance. Among the metal oxides, it is preferable to use Ca₃Co₄O₉ as a p-type material and CaMnO₃ as an n-type material. Ca₃Co₄O₉ and CaMnO₃ have particularly superior oxidation resistance at high temperatures in the atmosphere and also have high thermoelectric conversion performance.

The second substrate 7 has, for example, a rectangular shape and covers upper end sides of the thermoelectric conversion elements 3, 4. The second substrate 7 is arranged so as to be parallel and opposite to the first substrate 2. There are no particular restrictions on the second substrate 7, like the first substrate 2, as long as it has an electrical insulation property and a thermal conduction property, and the second substrate 7 can be made using a material such as alumina, aluminum nitride, magnesia, silicon carbide, zirconia, or mullite.

Each second electrode 6 electrically connects top end faces of p-type thermoelectric conversion element 3 and n-type thermoelectric conversion element 4 adjacent to each other, and is formed on the second substrate 7. This second electrode 6 can also be produced in the same manner as the first electrode and is also preferably bonded through a joint material 9 to each thermoelectric conversion element. The p-type thermoelectric conversion elements 3 and the n-type thermoelectric conversion elements 4 can be those with a metal layer on a surface opposed to the second electrode 6.

The p-type thermoelectric conversion elements 3 and the n-type thermoelectric conversion elements 4, on the whole, are electrically connected in series to one another by the second electrodes 6 and the first electrodes 8. As shown in FIG. 1, the p-type thermoelectric conversion element 3 and the n-type thermoelectric conversion element forming the two ends of the group of p-type thermoelectric conversion elements 3 and n-type thermoelectric conversion elements 4 electrically connected in series to one another on the whole will be referred to as E1 and E2, respectively. The p-type thermoelectric conversion element E1 forming the end is arranged on an one end portion electrode layer 8a made of the similar material as the first electrodes. The n-type thermoelectric conversion element E2 forming the end is arranged on an other end portion electrode layer 8b made of the similar material as the second electrodes.

In the thermoelectric conversion module 1 of the present embodiment, as shown in FIG. 2, the height of the bottom face 2u of the one end portion 2A of the first substrate 2 is higher than the height of the bottom face 2u of the other end portion 2B and the height of the top face 2t of the one end portion 2A of the first substrate 2 is also higher than the height of the top face 2t of the other end portion 2B. Particularly, in the present embodiment, the one end portion 2A of the first substrate 2 has an eaves shape. While there are no particular restrictions on a projecting length L (cf. FIG. 2) in the longitudinal direction (X-direction) of the one end portion 2A, the projecting length L is preferably approximately 0.5 to 5 cm. The longitudinal (X-directional) length of the other end portion 2B is preferably not less than the projecting length L of the one end portion 2A. A width W (cf. FIG. 1) of the one end portion 2A is preferably set so as to be equivalent to a width of the other end portion 2B.

Referring back to FIG. 2, a difference D between the height of the bottom face 2u of the one end portion 2A and the height of the bottom face 2u of the other end portion 2B is preferably nearly equal to the thickness of the other end portion 2B of the first substrate 2.

Furthermore, a through hole 12 penetrating the first substrate 2 is formed in the one end portion 2A. The through hole 12, as shown in FIG. 1, is preferably formed near the p-type thermoelectric conversion element E1 at the end of the group of p-type thermoelectric conversion elements 3 and n-type thermoelectric conversion elements 4 connected in series to one another, in the one end portion 2A. The one end portion electrode layer 8a to which the bottom face of the p-type thermoelectric conversion element E1 is bonded, as shown in FIG. 2, extends to the one end portion 2A on the top face 2t of the first substrate 2 and is further formed through the interior surface of the through hole 12 to a surrounding region around the through hole 12 in the bottom face 2u of the one end portion 2A.

On the other hand, a through hole 13 penetrating the first substrate 2 is formed in the other end portion 2B. The through hole 13 is formed, as shown in FIG. 1, in such a manner that a distance 13X thereof from an end face in the negative X-direction of the first substrate 2 is approximately equal to a distance 12X of the through hole 12 from an end face in the positive X-direction of the first substrate. Furthermore, the through hole 13 is formed in such a manner that a distance 13Y thereof from an end face in the negative Y-direction of the first substrate 2 is approximately equal to a distance 12Y of the through hole 12 from the end face in the negative Y-direction of the first substrate. Furthermore, the diameter of the through hole 13 is preferably approximately equal to that of the through hole 12. Furthermore, the other end portion electrode layer 8b to which the bottom face of the n-type thermoelectric conversion element E2 is bonded is formed so as to extend to the other end portion 2B on the top face 2t of the first substrate 2 and on a surrounding region around the through hole 13.

The through holes 12, 13 can be formed by a well-known method. The one end portion electrode layer 8a and the other end portion electrode layer 8b can also be readily formed by, for example, a thin film technology such as sputtering and evaporation, screen printing, plating, or thermal spraying.

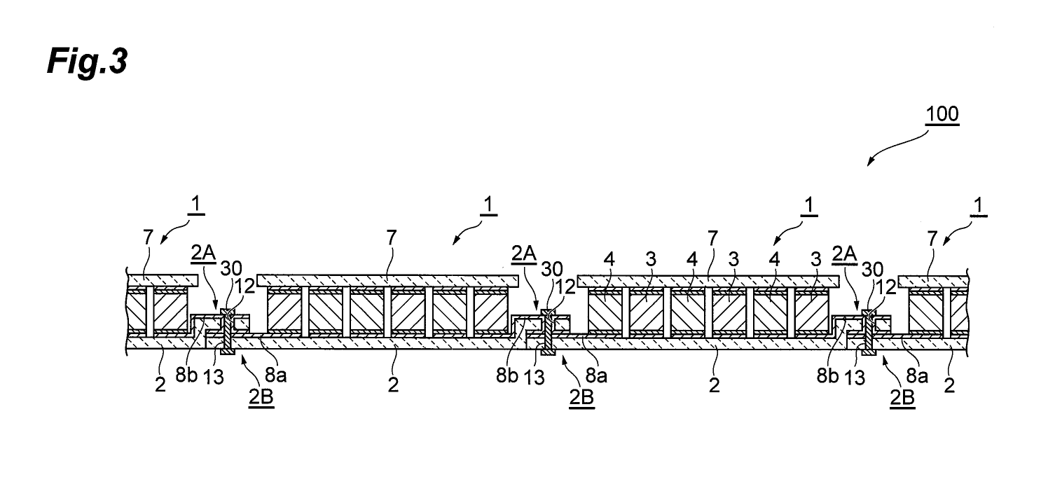

The below will describe a thermoelectric conversion module block using the thermoelectric conversion modules according to the present embodiment, with reference to FIG. 3.

The thermoelectric conversion module block 100 of the present embodiment has a plurality of thermoelectric conversion modules 1 as described above, the one end portion 2A of the first substrate 2 of one thermoelectric conversion module 1 is superimposed on the other end portion 2B of the second substrate 2 of another thermoelectric conversion module 1, and each pair of first substrates 2 are secured by a fixing member 30 penetrating through the through hole 12 of the one end portion 2A and the through hole 13 in the other end portion 2B.

There are no particular restrictions on the fixing member 30 and examples of fixing members applicable herein include rivets, bolts and nuts. The point is that the fixing member can secure a pair of second substrates 2, 2 in close contact. There are no particular restrictions on a material of the fixing member, and it can be a conductor or an insulator.

In the present embodiment, the one end portion 2A of the first substrate 2 has the level difference from the other end portion 2B and it can be used to achieve easy superposition of the one end portion 2A of the first substrate 2 of one thermoelectric conversion module 1 on the other end portion 2B of the first substrate 2 of another thermoelectric conversion module 1; the second substrates 2, 2 are superimposed on each other in this manner and secured with the fixing member 30 penetrating through each of the through holes 12, 13 of the pair of second substrates 2, 2, whereby the two substrates can be readily secured in close contact so as to surely bring the one end portion electrode layer 8a and the other end portion electrode layer 8b into contact with each other, thereby allowing the thermoelectric conversion modules 1, 1 to be readily electrically connected to each other. Since the thermoelectric conversion modules 1 are secured to each other with the fixing member 30 penetrating through the through holes 12, 13 of the pair of first substrates 2 together, the mechanical structure of the thermoelectric conversion module block 100 is not maintained mainly by the electrodes but maintained mainly by the fixing members 30 and the first substrates 2. Therefore, the mechanical strength of the thermoelectric conversion module block 100 is also high and breakage or the like of the joint part due to vibration or thermal stress is also suppressed more than in the case where the projecting electrodes are bonded to each other. Accordingly, it becomes easy to make the thermoelectric conversion module block 10 operate stably for long periods of time.

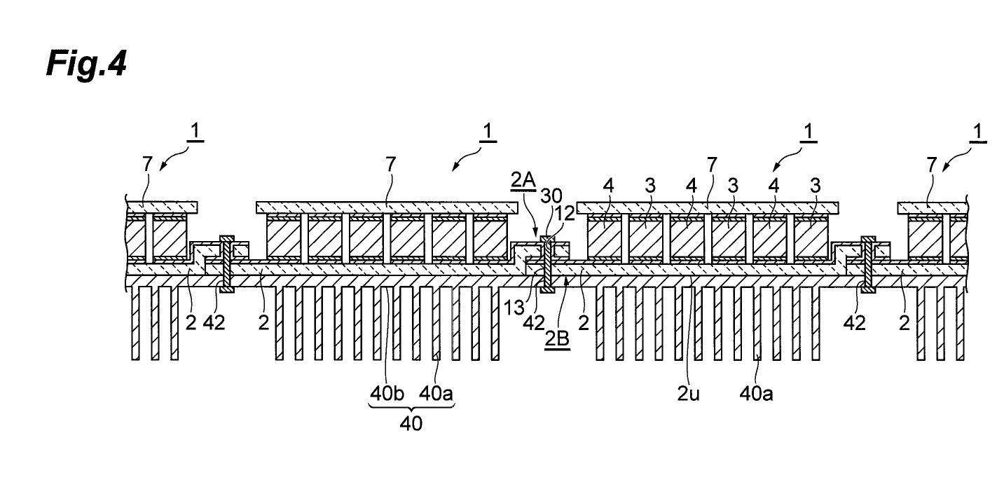

The following will describe a modification example of the thermoelectric conversion module block with reference to FIG. 4. In the present modification example, a heat sink 40 is arranged on the bottom faces 2u of the second substrates 2. An example of the heat sink 40 is, as shown in FIG. 4, one in which a number of fins 40a stand on a plate member 40b. There are no particular restrictions on a material of the heat sink 40 as long as it has a high coefficient of thermal conductivity and examples of such materials include metal materials such as aluminum and stainless steel.

Through holes 42 are formed in the plate member 40b of the heat sink 40 and the fixing members 30 further penetrate through the respective through holes 42 of the plate member 40b of the heat sink 40 in addition to the pair of first substrates 2, thereby securing the paired first substrates and heat sink 40 together in close contact. The present embodiment also facilitates fixation of the heat sink 40 and can also enhance heat dissipation efficiency.

The present invention is not limited only to the above embodiments but can also be modified in various ways.

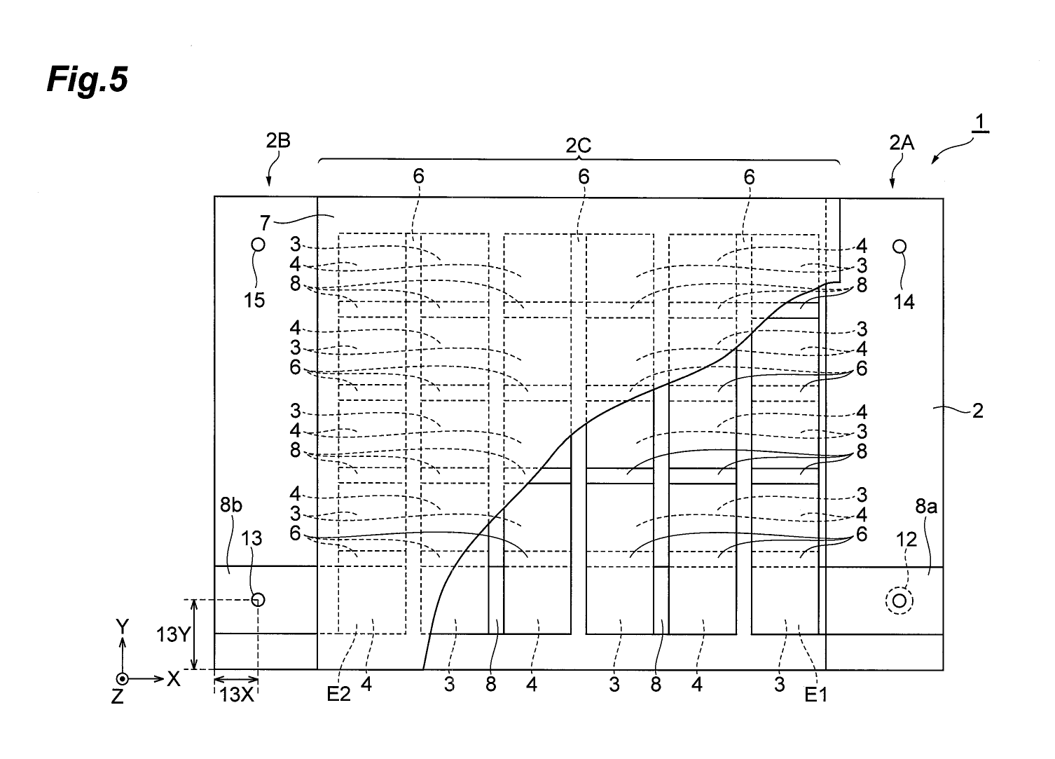

For example, it is also possible to adopt a configuration as shown in FIG. 5 wherein a through hole 14 is further provided in the one end portion 2A, a through hole 15 is further provided at a position corresponding to the through hole 14 as the through hole 13 is, in the other end portion 2B, and a pair of thermoelectric conversion modules 1 are secured in close contact further using the fixing member 30 penetrating through these through holes 14, 15. While there are no particular restrictions on the positions of the through holes 14, 15, they are preferably positions away from the other through holes 12, 13. It is, of course, needless to mention that the number of through holes may be further increased.

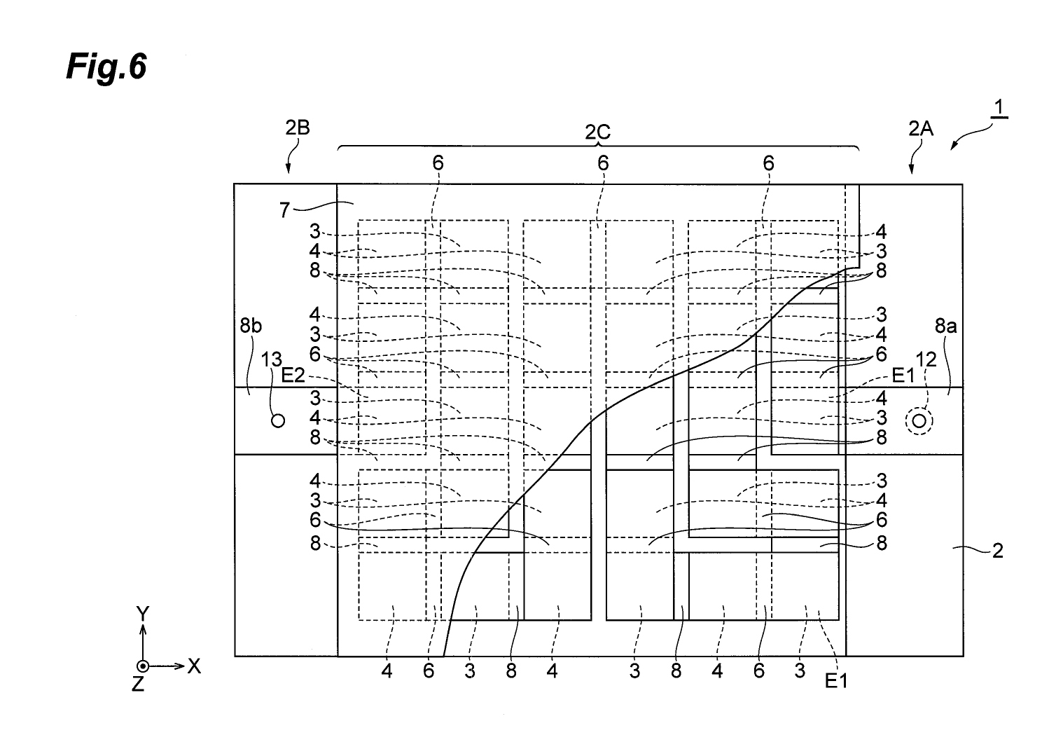

There are no particular restrictions on the place of the one end portion electrode layer 8a in the one end portion 2A, and for example, the one end portion electrode layer 8a can be provided in a central region in the Y-direction, as shown in FIG. 6, and in this case, the other end portion electrode layer 8b can also be arranged in a central region in the Y-direction in the other end portion 2B, corresponding thereto.

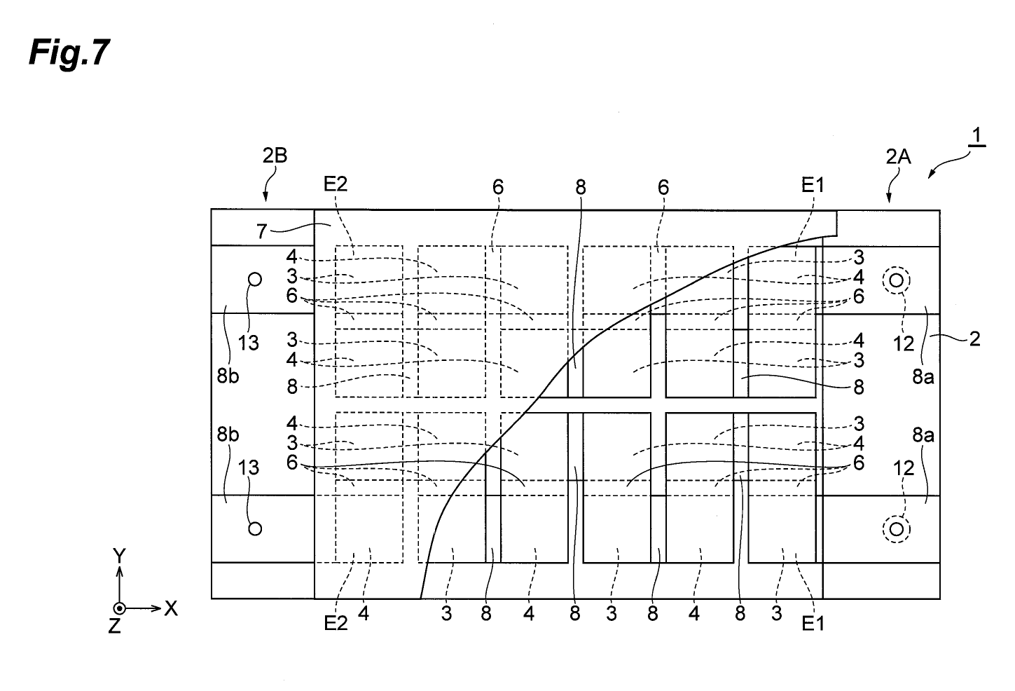

While in the above embodiments only one group of thermoelectric conversion elements connected in series to one another are provided on the substrate, it is also possible, as shown in FIG. 7, to provide, on the substrate, a plurality of groups of thermoelectric conversion elements connected in series to one another, and in this case, the module has multiple combinations of (through hole 12 and one end portion electrode layer 8a) and (through hole 13 and other end portion electrode layer 8b).

While in the above embodiments the p-type thermoelectric conversion element 3 is connected to the one end portion electrode layer 8a and the n-type thermoelectric conversion element 4 is connected to the other end portion electrode layer 8b, it is also possible to adopt a configuration wherein the n-type thermoelectric conversion element 4 is connected to the one end portion electrode layer 8a and the p-type thermoelectric conversion element 3 is connected to the other end portion electrode layer 8b.

While in FIG. 2 the heights of the top face 2t and the bottom face 2u in the central portion 2C are equal to the heights of the top face 2t and the bottom face 2u, respectively, of the other end portion 2B, the present invention is not limited only to this setup. The heights of the top face 2t and the bottom face 2u in the central portion 2C can be set to be equal to, for example, the heights of the top face 2t and the bottom face 2u, respectively, in the one end portion 2A. The heights in the central portion 2C can also be set completely independently of the heights of the top face and the bottom face in the one end portion and the other end portion.

While in the above embodiments the thermoelectric conversion elements are arrayed in the matrix pattern, there are no particular restrictions on the arrangement method, and for example, they can be arrayed in a line.

While in the above embodiments the first substrate 2 has the rectangular shape, the one end portion 2A is formed on one longitudinal side, and the other end portion 2B is formed on the other longitudinal side, it is also possible to optionally and suitably set the shape of the first substrate, the arrangement of the one end portion 2A and the other end portion 2B, and the positions of the through holes 12, 13 and others, according to the shape of the thermoelectric conversion module block expected to obtain.

While in the above embodiments the thermoelectric conversion module 1 has the second substrate 7, the present invention can also be carried out without the second substrate 7 as long as the module has the second electrodes 6.

### LIST OF REFERENCE SIGNS

1 thermoelectric conversion module; 2 first substrate; 2t top face; 2u bottom face; 2A one end portion; 2B other end portion; 2C central portion; 3 p-type thermoelectric conversion elements; 4 n-type thermoelectric conversion elements; 6 second electrodes; 7 second substrate; 8 first electrodes; 9 joint material; 12, 13 through holes; 100 thermoelectric conversion module block.

1. A thermoelectric conversion module comprising:
a substrate having a top face and a bottom face opposing each other; and a plurality of thermoelectric conversion elements arranged on the top face of the substrate and electrically connected in series to one another,
wherein the bottom face of one end portion of the substrate is higher than the bottom face of the other end portion of the substrate and the top face of the one end portion of the substrate is higher than the top face of the other end portion of the substrate,
wherein a through hole is formed in each of the one end portion and the other end portion of the substrate,
wherein in the one end portion of the substrate, an one end portion electrode layer electrically connected to one end of the plurality of thermoelectric conversion elements is provided ranging from the top face through an interior surface of the through hole to a surrounding region around the through hole in the bottom face, and
wherein in the other end portion of the substrate, an other end portion electrode layer electrically connected to the other end of the plurality of thermoelectric conversion elements is provided on a surrounding region around the through hole in the top face.

2. A thermoelectric conversion module block comprising a plurality of said thermoelectric conversion modules according to claim 1, wherein the one end portion of the substrate of one said thermoelectric conversion module is superimposed on the other end portion of the substrate of another said thermoelectric conversion module and wherein each pair of substrates are secured by a fixing member penetrating through the through hole in the one end portion and the through hole in the other end portion.

3. The thermoelectric conversion module block according to claim 2, wherein a heat sink with through holes corresponding to the through holes of the substrates are arranged on the bottom faces of the substrates and wherein the fixing member further penetrates through the through hole of the heat sink to secure the heat sink to the pair of substrates.
